(19) United States
(12) Patent Application Publication
(10) Pub. No.: US 2025/0287502 A1
(43) Pub. Date: Sep. 11, 2025

(54) CIRCUIT BOARD AND MANUFACTURING METHOD THEREOF

(71) Applicant: SAMSUNG ELECTRO-MECHANICS CO., LTD., Suwon-si (KR)

(72) Inventors: Yangje Lee, Suwon-si (KR); Junghoon Jang, Suwon-si (KR); Changgon Kim, Suwon-si (KR)

(73) Assignee: SAMSUNG ELECTRO-MECHANICS CO., LTD., Suwon-si (KR)

(21) Appl. No.: 19/051,059

(22) Filed: Feb. 11, 2025

(30) Foreign Application Priority Data
Mar. 8, 2024 (KR) 10-2024-0032985
Nov. 22, 2024 (KR) 10-2024-0168943

(51) Int. Cl. H05K 1/11; H05K 3/18; H05K 3/40; H05K 3/42

(52) U.S. Cl. CPC H05K 1/113; H05K 3/184; H05K 3/4076; H05K 3/423; H05K 3/425; H05K 2201/09536; H05K 2201/096; H05K 2203/072; H05K 2203/0723

(57) ABSTRACT

A disclosed circuit board may include an insulating layer having a via hole penetrating in one direction, a pad disposed on the insulating layer to cover the via hole, and a circuit wiring disposed on the insulating layer. The pad and the circuit wiring may include a first plurality of metal layers and a second plurality of metal layers, respectively, and the number of the first plurality of metal layers of the pad may be greater than that of the second plurality of metal layers of the circuit wiring.

### CROSS-REFERENCE TO RELATED APPLICATION

This application claims priority to and the benefit of Korean Patent Application No. 10-2024-0032985 filed in the Korean Intellectual Property Office on Mar. 8, 2024, and Korean Patent Application No. 10-2024-0168943 filed in the Korean Intellectual Property Office on Nov. 22, 2024, the entire contents of which are incorporated herein by reference.

### BACKGROUND OF THE INVENTION

### (a) Field of the Invention

The present disclosure relates to a circuit board and a manufacturing method thereof.

### (b) Description of the Related Art

As electronic devices in the IT field, including mobile phones, become lighter, thinner, shorter, and smaller, the circuit integration density is increasing and the number of integrated circuits for input/output is increasing, so the width of circuit patterns applied to printed circuit boards for package is becoming miniaturized.

Reducing line width and space is a core technology for wiring fine circuits. However, it is difficult to miniaturize the circuit due to process-related reasons such as forming circuit patterns by plating and etching.

### SUMMARY OF THE INVENTION

The present disclosure attempts to provide a circuit board and a manufacturing method thereof capable of reducing circuit design constraints and forming a fine circuit pattern.

However, the problem to be solved by embodiments of the present disclosure is not limited to the above-described problems and can be variously extended within the scope of the technical concept included in the present disclosure.

A circuit board according to an embodiment may include an insulating layer having a via hole penetrating in one direction, a pad disposed on the insulating layer to cover the via hole, and a circuit wiring disposed on the insulating layer. The pad and the circuit wiring may include a first plurality of metal layers and a second plurality of metal layers, respectively, and the number of the first plurality of metal layers of the pad may be greater than that of the second plurality of metal layers of the circuit wiring.

The pad may include a greater number of electroplating layers than the circuit wiring.

The pad and the wiring may include at least one electroless plating layer respectively, and the electroless plating layer of the circuit wiring may have a thickness greater than that of the pad.

The pad may comprise a first pad seed layer pattern, an extending portion of a through via, a second pad seed layer pattern, and a pad electroplating layer pattern, sequentially stacked on the insulating layer, and the circuit wiring may comprise a first circuit seed layer pattern, a second circuit seed layer pattern, and a circuit electroplating layer pattern sequentially stacked on the insulating layer. The extending portion of the through via may be extended in a direction perpendicular to the one direction from both ends of a penetrating portion of the through via extended in the one direction to cover an inner wall of the via hole.

The extending portion may be an electroplating pattern, and the first pad seed layer pattern, the second pad seed layer pattern, the first circuit seed layer pattern, and the second circuit seed layer pattern may be electroless plating layer patterns.

A thickness of the circuit electroplating layer pattern may be greater than that of the pad electroplating layer pattern.

The second pad seed layer pattern may cover at least a portion of a sidewall of the extending portion.

The pad electroplating layer pattern may cover at least a portion of a sidewall of the extending portion.

The penetrating portion may comprise a hollow portion penetrating in the one direction therein.

A circuit board according to an embodiment may further comprise a plug disposed in the hollow portion and protruding to outside of a surface of the insulating layer.

The extending portion may surround a portion of the plug protruding to the outside of the surface of the insulating layer.

A manufacturing method of a circuit board according to an embodiment may include forming a via hole penetrating a first insulating layer, forming a first seed layer on a surface of the first insulating layer in which the via hole is formed, forming a first mask pattern on the first seed layer to expose the via hole and a region of the first seed layer around the via hole, forming a through via having a hollow portion therein, on the region of the first seed layer exposed by the first mask pattern, forming a preliminary plug filling the hollow portion of the through via, planarizing the preliminary plug, the first mask pattern, and the through via, removing the first mask pattern remaining after the planarizing, forming a second seed layer on the first seed layer, an extending portion of the through via extended on the first insulating layer, and a plug formed by planarizing the preliminary plug, forming a second mask pattern exposing a region of the second seed layer on the plug and on at least a portion of the extending portion of the through via, and another region of the second seed layer spaced apart from the region of the second seed layer, and forming an electroplating layer pattern on the regions of the second seed layer exposed by the second mask pattern.

The manufacturing method of a printed circuit board may further include removing the second seed layer and the first seed layer exposed by the electroplating layer pattern, after removing the second mask pattern.

The manufacturing method of a printed circuit board may further include forming a second insulating layer on the first insulating layer to bury the electroplating layer pattern.

The forming of the electroplating layer pattern may comprise forming a pad electroplating layer pattern to have a step with the extending portion by plating in the region opened by the second mask pattern.

The forming of the pad electroplating layer pattern may comprise forming the pad electroplating layer pattern to cover a portion of the second seed layer extended on the first seed layer at one end.

The forming of the plug may comprise forming the plug to comprise a non-conductive material.

The manufacturing method of a printed circuit board may further include forming a copper foil (Cu foil) layer on the first insulating layer, wherein the forming of the first seed layer may comprise forming the first seed layer on the copper foil layer.

The manufacturing method of a printed circuit board may further include forming a pad by sequentially stacking the copper foil layer, the first seed layer, the extending portion of the through via, the second seed layer, and the electroplating layer pattern on the first insulating layer.

The manufacturing method of a printed circuit board may further include forming a circuit wiring by sequentially stacking the copper foil, the first seed layer, the second seed layer, and the electroplating layer pattern, on the first insulating layer.

The forming of the first seed layer may comprise forming the first seed layer by electroless plating.

The forming of the second seed layer may comprise forming the second seed layer by electroless plating.

A circuit board and a manufacturing method of the circuit board according to an embodiment, circuit design constraints due to metal thicknesses of circuit layers may be reduced, and circuit patterns may be miniaturized.

### BRIEF DESCRIPTION OF THE DRAWINGS

FIG. 1 is a cross-sectional view schematically illustrating a circuit board according to an embodiment.

FIG. 2 is an enlarged cross-sectional view according to an example of area A of FIG. 1.

FIG. 3 to FIG. 12 are cross-sectional views illustrating a manufacturing method of a circuit board according to an embodiment.

FIG. 13 is a cross-sectional view schematically illustrating a circuit board according to another embodiment.

FIG. 14 is an enlarged cross-sectional view according to an example of area A of FIG. 13.

FIG. 15 is a cross-sectional view illustrating a manufacturing method of the circuit board shown in FIG. 13.

### DETAILED DESCRIPTION OF THE EMBODIMENTS

Hereinafter, various embodiments of the present disclosure will be described in detail so that a person of ordinary skill in the technical field to which the present disclosure belongs can easily implement it with reference to the accompanying drawings. In order to clearly describe the present disclosure, parts unrelated to the description are omitted in the drawings, and the same reference numerals are designated to the same or similar elements throughout the specification. In addition, some elements in the accompanying drawings are exaggerated, omitted, or schematically illustrated, and the size of each component does not fully reflect the actual size.

The accompanying drawings are provided only in order to allow embodiments disclosed in the present specification to be easily understood and are not to be interpreted as limiting the technical concept disclosed in the present specification, and it is to be understood that the present disclosure includes all modifications, equivalents, and substitutions without departing from the scope and concept of the present disclosure.

Terms including ordinal numbers such as first, second, and the like will be used only to describe various components and are not to be interpreted as limiting these components. The terms are only used to differentiate one component from other components.

Furthermore, it will be understood that when an element such as a layer, film, region, or substrate is referred to as being “on” another element, it can be directly on the other element or intervening elements may also be present. On the contrary, when an element is referred to as being “directly on” another element, there are no intervening elements present. Furthermore, in the specification, the word “on” or “above” means positioned on or below the object portion and does not necessarily mean positioned on the upper side of the object portion based on a gravitational direction.

It will be further understood that terms “comprises/includes” or “have” used throughout the specification specify the presence of stated features, numerals, steps, operations, elements, parts, or a combination thereof, but do not preclude the presence or addition of one or more other features, numerals, steps, operations, elements, parts, or a combination thereof. Accordingly, unless explicitly described to the contrary, the word “comprise” and variations such as “comprises” or “comprising” will be understood to imply the inclusion of stated components but not the exclusion of any other components.

Furthermore, throughout the specification, the phrase “in a plan view” means when an object portion is viewed from above, and the phrase “in a cross-sectional view” means when a cross-section taken by vertically cutting an object portion is viewed from the side.

Throughout the specification, “connected” means that two or more elements are not only directly connected, but two or more elements may be connected indirectly through other elements, physically connected as well as being electrically connected, or it may be referred to by different names depending on the location or function but may mean integral.

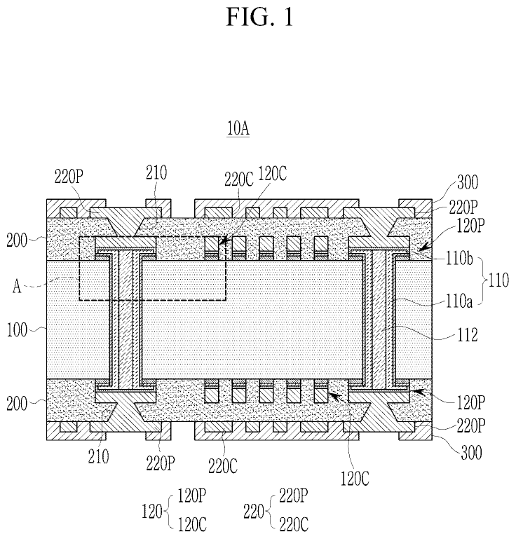

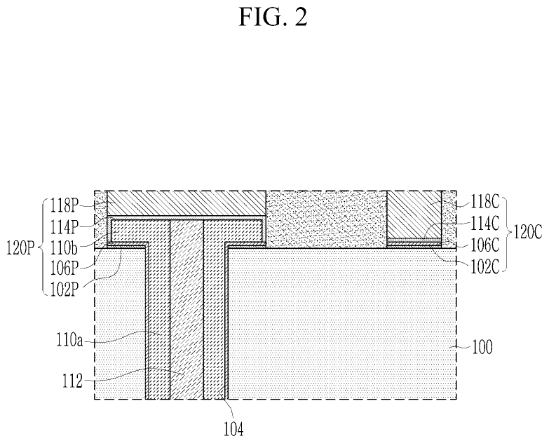

Hereinafter, a circuit board 10A according to an embodiment will be described with reference to FIG. 1 and FIG. 2.

FIG. 1 is a cross-sectional view schematically illustrating a circuit board according to an embodiment. FIG. 2 is an enlarged cross-sectional view according to an example of area A of FIG. 1.

Referring to FIG. 1 and FIG. 2, the circuit board 10A according to an embodiment may include a first insulating layer 100 provided as a core layer. A first circuit layer 120 may be disposed on both surfaces of the first insulating layer 100, and the first circuit layer 120 may include a first pad 120P and a first circuit wiring 120C.

A second insulating layer 200 may be disposed on the first insulating layer 100 to cover the first circuit layer 120. A second circuit layer 220 including a second pad 220P, and a second circuit wiring 220C may be disposed on the second circuit layer 200. The second pad 220P may be connected to the first pad 120P through a stack via 210 penetrating the second insulating layer 200.

A passivation layer 300 may be disposed on the second insulating layer 200. The passivation layer 300 may protect the internal element from external physical and chemical damage and the like. The passivation layer 300 may cover a surface of the second insulating layer 200, and expose at least a portion of the second pad 220P. The passivation layer 300 may be formed of a photo-sensitive resin, for example, a solder resist layer.

The first insulating layer 100 and the second insulating layer 200 may include an insulating material. The insulating material may include a thermosetting resin such as an epoxy resin, a thermoplastic resin such as polyimide, or these resins containing an inorganic filler such as silica and a reinforcing material such as glass fiber. The insulating material may be a photosensitive material or a non-photosensitive material. For example, Solder Resist (SR), Ajinomoto-Build up Film (ABF), FR-4, Bismaleimide Triazine (BT), Resin Coated Copper (RCC) or Copper Clad Laminate (CCL), etc. may be used as the insulating material, but are not limited thereto. The insulating material may include polymer material. For example, prepreg may be used, but is not limited thereto. Furthermore, the first insulating layer 100 is illustrated as one layer in FIG. 1 and FIG. 2 but is not limited thereto. A plurality of thin layers may be stacked to form the first insulating layer 100.

Each of the first and the second circuit layers 120 and 220 may transfer a signal inside the circuit board 10A. Metal material may be used as a material for each of the first and the second circuit layers 120 and 220. The metal material may include copper (Cu), aluminum (Al), silver (Ag), tin (Sn), gold (Au), nickel (Ni), lead (Pb), titanium (Ti), or an alloy thereof. Each of the first and the second circuit layers 120 and 220 may perform various functions depending on a design thereof, such as ground pattern, power pattern, signal pattern, etc. Each of these patterns may have a line shape, a plane shape, or a pad shape. In the case of a circuit layer located in the outermost layer among the plurality of circuit layers, it may function as a pad for connection to another board or component.

The first insulating layer 100 may have a via hole 104 penetrating in a first direction therein. The first direction may be a stacking direction. A through via 110 may have a hollow portion penetrating in the first direction therein and be extended to fill the via hole 104. A plug 112 may fill the hollow portion and protrude to the outside of a surface of the insulating layer 100. The through via 110 may include a penetrating portion 110a extended in the first direction to cover an inner wall of the via hole 104. Furthermore, the through via 110 may include an extending portion 110b extended in a direction perpendicular to the first direction from both ends of the penetrating portion 110a and surrounding a portion of the plug 112 protruding to the outside of the surface of the first insulating layer 100. The first pads 120P on both surfaces of the first insulating layer 100 may be connected to each other by the through via 110.

A metal material may be used as a material of each of the through via 110 and the stack via 210. The metal material may include copper (Cu), aluminum (Al), silver (Ag), tin (Sn), gold (Au), nickel (Ni), lead (Pb), titanium (Ti), or an alloy thereof. Each of the through via 110 and the stack via 210 may include a signal via, a ground via, a power via, and the like according to a circuit design.

The plug 112 may include plugging ink having insulating nature. The plug 112 may fill an empty space in the via hole 104 to prevent oxidation of the through via 110.

Hereinafter, the first pad 120P and the first circuit wiring 120C of the circuit board 10A according to an embodiment will be described in detail with reference to FIG. 1 and FIG. 2.

Referring to FIG. 1 and FIG. 2, the first pad 120P and the first circuit wiring 120C may be disposed on the first insulating layer 100 and have different layer structures.

The first pad 120P may include a first pad copper foil layer pattern 102P and a first pad seed layer pattern 106P, which are interposed between the extending portion 110b of the through via 110 and the first insulating layer 100 and sequentially stacked on the first insulating layer 100 in the first direction. Furthermore, the first pad 120P may include a second pad seed layer pattern 114P and a first pad electroplating layer pattern 118P, which are sequentially stacked on the extending portion 110b. The second pad seed layer pattern 114P may cover an upper surface of the extending portion 110b. In some cases, the second pad seed layer pattern 114P may cover the upper surface of the extending portion 110b and may cover at least a portion of a side surface of the extending portion 110b. As described later, the first pad seed layer pattern 106P and the second pad seed layer pattern 114P may be metal layers formed by electroless plating, for example, Cu layers. In addition, the extending portion 110b and the first pad electroplating layer pattern 118P may be metal layers, for example, Cu layers, formed on the first pad seed layer pattern 106P and the second pad seed layer pattern 114P by electroplating respectively.

On the other hand, the first circuit wiring 120C may include a first circuit copper foil layer pattern 102C, a first circuit seed layer pattern 106C, a second circuit seed layer pattern 114C, and a first circuit electroplating layer pattern 118C, which are sequentially stacked on the first insulating layer 100. The first and the second circuit seed layer patterns 106C and 114C may be metal layers formed by electroless plating, for example, Cu layers. Furthermore, the first circuit electroplating layer pattern 118C may be a metal layer formed on the second circuit seed layer pattern 114C by electroplating, for example, a Cu layer.

The first pad 120P may include two electroplating layers, the extending portion 110b and the first pad electroplating layer pattern 118P, and one electroless plating layer, the second pad seed layer pattern 114P, interposed therebetween. On the other hand, the first circuit wiring 120C may include two electroless plating layers sequentially stacked, the first circuit seed layer pattern 106C and the second circuit seed layer pattern 114C, and one electroplating layer, the first circuit electroplating layer pattern 118C.

The two electroless plating layers sequentially stacked, the first circuit seed layer pattern 106C and the second circuit seed layer pattern 114C, may be seen as a single layer. In this case, the electroless plating layer of the first circuit wiring 120C may have a greater thickness than the electroless plating layer of the first pad 120P.

The first pad 120P and the first circuit wiring 120C may have substantially the same thickness, but as described later, the first pad electroplating layer pattern 118P and the first circuit electroplating layer pattern 118C formed by the same process may have different thicknesses. That is, the thickness of the first circuit electroplating layer pattern 118C may be greater than that of the first pad electroplating layer pattern 118P.

As described above, according to an embodiment of a circuit board, circuit design constraints due to metal thicknesses of circuit layers are reduced, and miniaturized circuit patterns may be implemented.

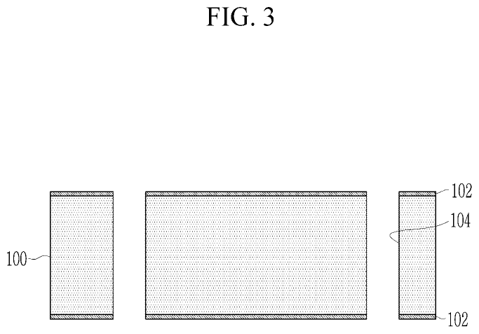

Hereinafter, a manufacturing method of the circuit board 10A according to an embodiment will be described with reference to FIG. 3 to FIG. 12.

FIG. 3 to FIG. 12 are cross-sectional views illustrating a manufacturing method of a circuit board according to an embodiment.

Referring to FIG. 3, the first insulating layer 100 having a copper foil layer 102 formed on both surfaces thereof may be prepared. The copper foil layer 102 may be formed by stacking and pressing Cu-foil on both surfaces of the first insulating layer 100. The via hole 104 may be formed to penetrate the first insulating layer 100 and the copper foil layer 102. The via hole 104 may be formed of plurality by laser processing, mechanical drill processing, or the like.

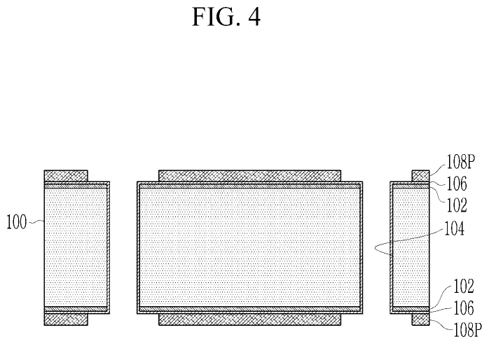

Referring to FIG. 4, a first seed layer 106 may be formed on a surface of the first insulating layer 100 in which the via hole 104 is formed. The first seed layer 106 may be formed on the copper foil layer 102 and on an inner wall of the via hole 104. The first seed layer 106 may be formed of copper (Cu) layer by electroless plating. A first mask pattern 108P may be formed on the first seed layer 106 to expose the via hole 104 and the first seed layer 106 around the via hole 104. The first mask pattern 108P may expose a region positioned along an edge of the via hole 104 on the first seed layer 106. The first mask pattern 108P may be patterned by exposing and developing a photosensitive dry film.

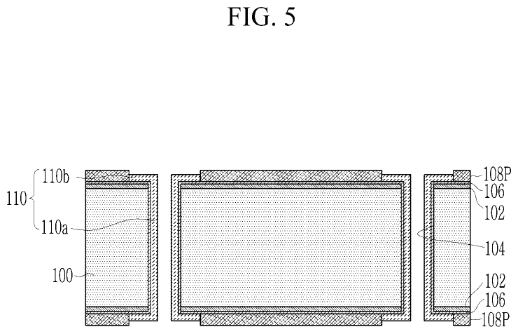

Referring to FIG. 5, the through via 110 may be formed on the first seed layer 106 exposed by the first mask pattern 108P. The through via 110 may include the penetrating portion 110a on the inner wall of the via hole 110, and extending portion 110b connected to the penetrating portion 110a and extended to upper and lower surfaces of the first insulating layer 100. The through via 110 may be formed by electroplating on the exposed first seed layer 106 using the first mask pattern 108P as a plating mask and may be formed of copper (Cu).

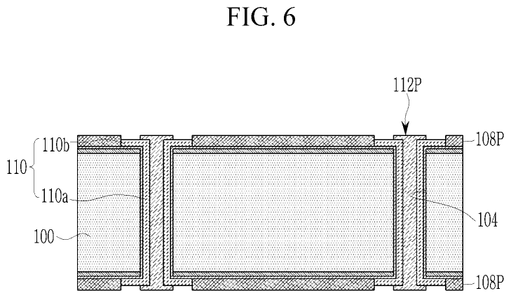

Referring to FIG. 6, a preliminary plug 112P may be formed to fill inside of the via hole 104 in which the through via 110 is formed, and extended on the extending portion 110b. The preliminary plug 112P may be formed by printing an insulating ink.

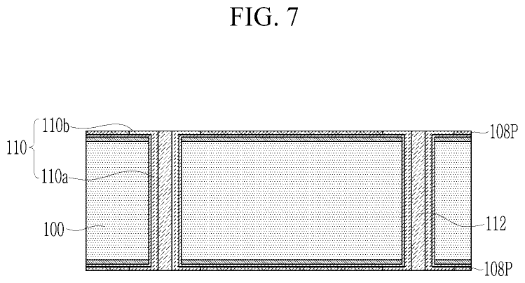

Referring to FIG. 7, the preliminary plug 112P of a portion formed on the extending portion 110b of the through via 110, the extending portion 110b of the through via 110, and the first mask pattern 108P may be polished to planarize their surfaces. In this process, the preliminary plug 112P of a portion extended on the extending portion 110b may be removed to form the plug 112. In addition, the thicknesses of the extending portion 110b and the first mask pattern 108P may be decreased, and surfaces of the plug 112, the extending portion 110b, and the first mask pattern 108P may be disposed on substantially the same plane. The plug 112 may be surrounded by the penetrating portion 110a of the through via 110. The plug may be formed to include a non-conductive material.

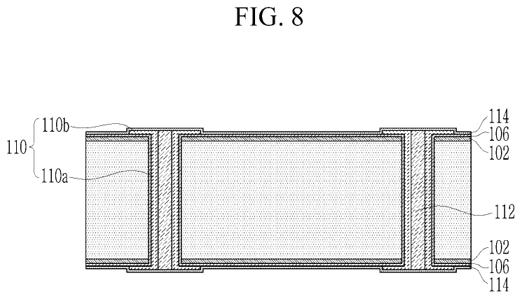

Referring to FIG. 8, after peeling off and removing the remaining first mask pattern 108P, a second seed layer 114 may be formed on the first seed layer 106, the extending portion 110b of the through via 110, and the plug 112. The second seed layer 114 may be formed of copper (Cu) by electroless plating.

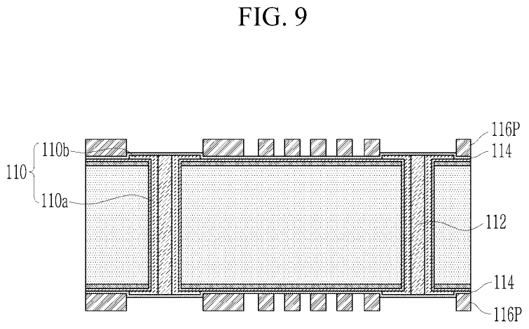

Referring to FIG. 9, a second mask pattern 116P may be formed on the second seed layer 114. The second mask pattern 116P may continuously expose the second seed layer 114 on the plug 112 and the second seed layer 114 on at least a portion of the extending portion 110b. In addition, the second mask pattern 116P may expose the second seed layer 114 of a region in which the circuit wiring is to be formed. The second mask pattern 116P may be patterned by exposing and developing a photosensitive dry film.

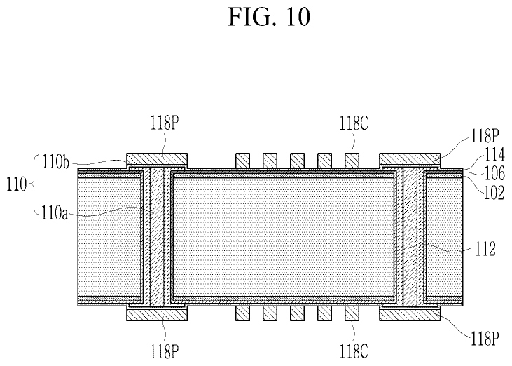

Referring to FIG. 9 and FIG. 10, the first pad electroplating layer pattern 118P and the first circuit electroplating layer pattern 118C may be formed on the exposed second seed layer 114 by using the second mask pattern 116P as a plating mask. The first pad electroplating layer pattern 118P and the first circuit electroplating layer pattern 118C may be formed of copper (Cu). Then, the second mask pattern 116P may be peeled off and removed.

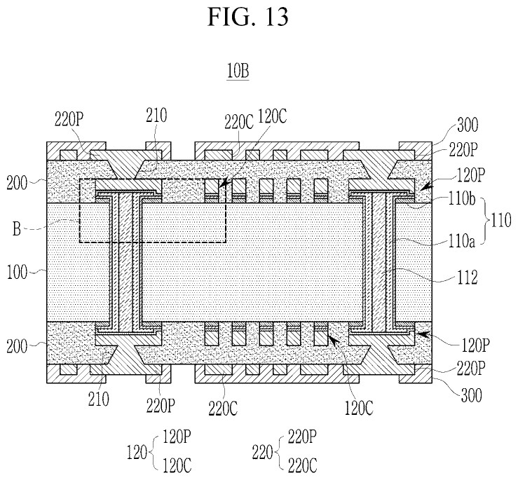

Meanwhile, when the second mask pattern 116P of FIG. 9 is formed to be partially or entirely spaced apart from the second seed layer 114 formed on the sidewall of the extending portion 110b, the first pad electroplating layer pattern 118P may be formed to partially or entirely cover the second seed layer 114 formed on the sidewall of the extending portion 110b (see FIG. 13).

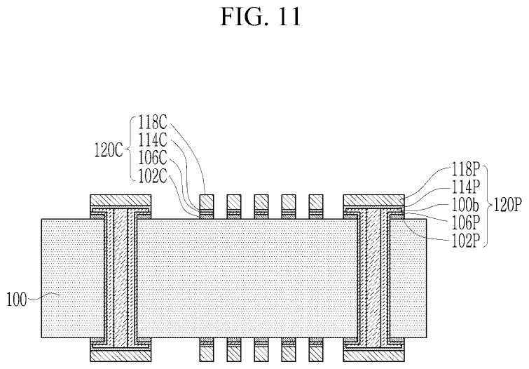

Referring to FIG. 11, after removing the second mask pattern 116P, an exposed portion of the second seed layer 114 and its underlying portion of the first seed layer 106 and the copper foil layer 102 may be removed to form the first pad 120P and the first circuit wiring 120C.

As a result, the first pad 120P may include the first pad copper foil layer pattern 102P, the first pad seed layer pattern 106P, an extending portion 110b of the through via 110, the second pad seed layer pattern 114P, and the first pad electroplating layer pattern 118P sequentially stacked on the first insulating layer 100. The first circuit wiring 120C may include the first circuit copper foil layer pattern 102C, the first circuit seed layer pattern 106C, the second circuit seed layer pattern 114C, and a first circuit electroplating layer pattern 118C sequentially stacked on the first insulating layer 100. While the first pad 120P may include two electroplating layers, the extending portion 110b and the first pad electroplating layer pattern 118P, the first circuit wiring 120C may include one electroplating layer, the first circuit electroplating layer pattern 118C. Furthermore, while the first pad 120P may be formed such that an electroplating layer is interposed between two electroless plating layers, the first circuit wiring 120C may be formed to include two electroless plating layers directly and entirely contacting with each other.

Meanwhile, the exposed portion of the second seed layer 114 and its underlying portion of the first seed layer 106 and the copper foil layer 102 may be removed by wet etching using a chemical solution, and depending on the degree or method of the etching, the second seed layer 114 on the sidewall of the extending portion 110b may be partially or entirely removed. For example, in case a chemical solution is sprayed in a direction perpendicular to the stacking direction, the second seed layer 114 on the side wall of the extending portion 110b may be partially remained.

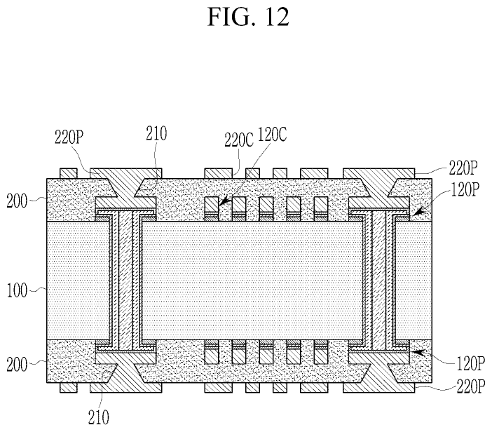

Referring to FIG. 12, a second insulating layer 200 may be formed on the first insulating layer 100 to bury the first pad 120P and the first circuit wiring 120C. Then, the second pad 220P and the second circuit wiring 220C may be formed on the second insulating layer 200. Furthermore, a build-up via 210 may be formed to penetrate the second insulating layer 200 and connect the first pad 120P and the second pad 220P to each other. The second pad 220P and the second circuit wiring 220C and the build-up via 210 may be formed by a wire forming process, for example, a subtractive process, an Additive Process (AP), a Semi Additive Process (SAP), or a Modified Semi Additive Process (MSAP).

Referring to FIG. 12 and FIG. 1, the passivation layer 300 exposing a portion of the second pad 220P may be formed on the second insulating layer 200 on which the second pad 220P and the second circuit wiring 220C are formed. The passivation layer 300 may be a solder resist layer formed by exposing and developing a photosensitive resin.

According to an embodiment of a manufacturing method of a circuit board, since the through via is formed after forming the mask pattern on the copper foil layer and the seed layer stacked on the insulating layer, the through via may be formed to be finer and more elaborate as compared with etching after plating on entire upper surface of the insulating layer.

In addition, according to an embodiment of a manufacturing method of a circuit board, by forming circuit wirings using the MSAP method, it is possible to reduce circuit design constraints due to the metal thickness of the circuit wirings without affecting the formation of through vias and plugs and to miniaturize the circuit.

Hereinafter, a circuit board 10B and a manufacturing method thereof according to another embodiment will be described.

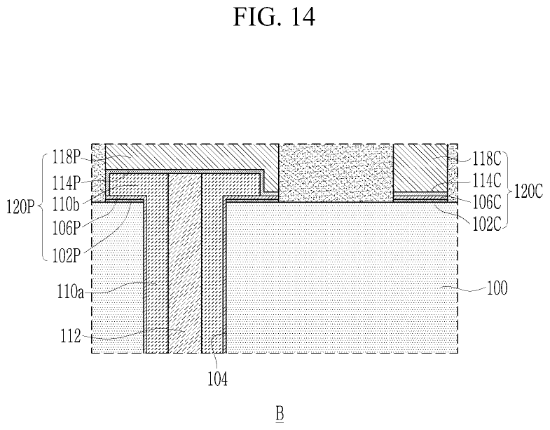

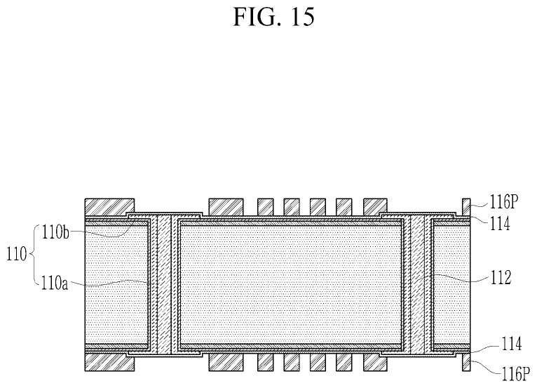

FIG. 13 is a cross-sectional view schematically illustrating a circuit board according to another embodiment. FIG. 14 is an enlarged cross-sectional view according to an example of area B of FIG. 13. FIG. 15 is a cross-sectional view illustrating a manufacturing method of the circuit board shown in FIG. 13.

Referring to FIG. 13 and FIG. 14, the circuit board 10B according to another embodiment is similar to the circuit board 10A according to an embodiment described with reference to FIG. 1 to FIG. 12. Detailed description may be omitted for the same elements.

Referring to FIG. 13 and FIG. 14, the circuit board 10B according to another embodiment may include the extending portion 110b and the first pad electroplating layer pattern 118P arranged with a step at one end, unlike the circuit board 10A according to the embodiment shown in FIG. 1 and FIG. 2. The first pad electroplating layer pattern 118P may include a portion that does not overlap the extending portion 110b in the stacking direction. The first pad electroplating layer pattern 118P may be disposed to expose a portion of the second pad seed layer pattern 114P from the first pad electroplating layer pattern 118P at one end and cover another portion of the second pad seed layer pattern 114P at the other end.

Referring to FIG. 15, the manufacturing method of the circuit board 10B according to another embodiment is similar to the manufacturing method of the circuit board 10A according to the embodiment described with reference to FIG. 3 to FIG. 12. Detailed description may be omitted for the same elements.

Referring to FIG. 13 and FIG. 15, in the manufacturing method of the circuit board 10B according to another embodiment, centers of an open region of the extending portion 110b and the second mask pattern 116P may not coincide, and a portion of the second mask pattern 116P may be formed to overlap the extending portion 110b in the stacking direction, unlike the manufacturing method of the circuit board 10A according to the embodiment shown in FIG. 3 and FIG. 12. Therefore, the second seed layer pattern 114P and the first pad electroplating layer pattern 118P may be formed to have step with the extending portion 110b by plating in the open region of the second mask pattern 116P. The second pad seed layer pattern 114P may be formed to extend on the first pad seed layer pattern 106P at one end thereof. The first pad electroplating layer pattern 118P may be formed to cover the second pad seed layer pattern 114P extended on the first pad seed layer pattern 106P at one end.

As described above, according to another embodiment of the circuit board and the manufacturing method thereof, by forming extending portions of through vias and circuit layers through separate plating process, rather than forming them simultaneously in a single plating process, it is possible to reduce circuit design constraints due to metal thickness of circuit layers without affecting the formation of through vias and plugs, and to miniaturize the circuit.

While embodiments of the present invention have been described above, the present disclosure is not limited thereto, and it is possible to perform various modifications within the scope of the claims, the detailed description, and the accompanying drawings, and it is natural that these modifications also fall within the scope of the present disclosure.

What is claimed is:

1. A circuit board comprising:
an insulating layer having a via hole penetrating in one direction;
a pad disposed on the insulating layer to cover the via hole; and
a circuit wiring disposed on the insulating layer,
wherein the pad and the circuit wiring comprise a first plurality of metal layers and a second plurality of metal layers, respectively, and
the number of the first plurality of metal layers of the pad is greater than that of the second plurality of metal layers of the circuit wiring.

2. The circuit board of claim 1, wherein:
the pad comprises a greater number of electroplating layers than the circuit wiring.

3. The circuit board of claim 1, wherein:
the pad and the circuit wiring comprise at least one electroless plating layer, respectively, and the electroless plating layer of the circuit wiring has a thickness greater than that of the pad.

4. The circuit board of claim 1, wherein:
the pad comprises a first pad seed layer pattern, an extending portion of a through via, a second pad seed layer pattern, and a pad electroplating layer pattern, sequentially stacked on the insulating layer, and
the circuit wiring comprises a first circuit seed layer pattern, a second circuit seed layer pattern, and a circuit electroplating layer pattern sequentially stacked on the insulating layer,
wherein the extending portion of the through via extends in a direction perpendicular to the one direction from both ends of a penetrating portion of the through via extended in the one direction to cover an inner wall of the via hole.

5. The circuit board of claim 4, wherein:
the extending portion is an electroplating pattern, and
the first pad seed layer pattern, the second pad seed layer pattern, the first circuit seed layer pattern, and the second circuit seed layer pattern are electroless plating layer patterns.

6. The circuit board of claim 4, wherein:
a thickness of the circuit electroplating layer pattern is greater than that of the pad electroplating layer pattern.

7. The circuit board of claim 4, wherein:
the second pad seed layer pattern covers at least a portion of a sidewall of the extending portion.

8. The circuit board of claim 4, wherein:
the pad electroplating layer pattern covers at least a portion of a sidewall of the extending portion.

9. The circuit board of claim 4, wherein:
the penetrating portion comprises a hollow portion penetrating in the one direction therein.

10. The circuit board of claim 9, further comprising:
a plug disposed in the hollow portion and protruding to outside of a surface of the insulating layer.

11. The circuit board of claim 10, wherein:
the extending portion surrounds a portion of the plug protruding to the outside of the surface of the insulating layer.

12. A manufacturing method of a circuit board, comprising:
forming a via hole penetrating a first insulating layer;
forming a first seed layer on a surface of the first insulating layer in which the via hole is formed;
forming a first mask pattern on the first seed layer to expose the via hole and a region of the first seed layer around the via hole;
forming a through via having a hollow portion therein, on the region of the first seed layer exposed by the first mask pattern;
forming a preliminary plug filling the hollow portion of the through via;
planarizing the preliminary plug, the first mask pattern, and the through via;
removing the first mask pattern remaining after the planarizing;
forming a second seed layer on the first seed layer, an extending portion of the through via extended on the first insulating layer, and a plug formed by planarizing the preliminary plug;
forming a second mask pattern exposing a region of the second seed layer on the plug and on at least a portion of the extending portion of the through via, and another region of the second seed layer spaced apart from the region of the second seed layer, and
forming an electroplating layer pattern on the regions of the second seed layer exposed by the second mask pattern.

13. The manufacturing method of claim 12, further comprising:
after removing the second mask pattern, removing the second seed layer and the first seed layer exposed by the electroplating layer pattern.

14. The manufacturing method of claim 12, further comprising:
forming a second insulating layer on the first insulating layer to bury the electroplating layer pattern.

15. The manufacturing method of claim 12, wherein:
the forming of the electroplating layer pattern comprises forming a pad electroplating layer pattern to have a step with the extending portion by plating in the region opened by the second mask pattern.

16. The manufacturing method of claim 15, wherein:
the forming of the pad electroplating layer pattern comprises forming the pad electroplating layer pattern to cover a portion of the second seed layer extended on the first seed layer at one end.

17. The manufacturing method of claim 12, wherein:
the forming of the plug comprises forming the plug to comprise a non-conductive material.

18. The manufacturing method of claim 12, further comprising:
forming a copper foil (Cu foil) layer on the first insulating layer,
wherein the forming of the first seed layer comprises forming the first seed layer on the copper foil layer.

19. The manufacturing method of claim 18, further comprising:
forming a pad by sequentially stacking the copper foil layer, the first seed layer, the extending portion of the through via, the second seed layer, and the electroplating layer pattern on the first insulating layer.

20. The manufacturing method of claim 18, further comprising:
forming a circuit wiring by sequentially stacking the copper foil, the first seed layer, the second seed layer, and the electroplating layer pattern, on the first insulating layer.

21. The manufacturing method of claim 12, wherein:
the forming of the first seed layer comprises forming the first seed layer by electroless plating.

22. The manufacturing method of claim 12, wherein:
the forming of the second seed layer comprises forming the second seed layer by electroless plating.

23. A circuit board comprising:
an insulating layer having a via hole penetrating in one direction;
a pad disposed on the insulating layer to cover the via hole, and including a pad seed layer pattern and a pad electroplating layer pattern disposed on the pad seed layer pattern; and
a circuit wiring disposed on the insulating layer, and including a circuit seed layer pattern and a circuit electroplating layer pattern disposed on the circuit seed layer pattern,
wherein a thickness of the circuit electroplating layer pattern disposed on the circuit seed layer pattern is greater than a thickness of the pad electroplating layer pattern disposed on the pad seed layer pattern to overlap the via hole.

24. The circuit board of claim 23, wherein:
the pad seed layer includes first and second pad seed layers, and
the pad further comprises an extending portion of a through via to be disposed between the first and second pad seed layers.

25. The circuit board of claim 24, wherein:
the extending portion of the through via is spaced apart from the circuit wiring.

26. The circuit board of claim 24, wherein:
the second pad seed layer pattern covers at least a portion of a sidewall of the extending portion.

27. The circuit board of claim 24, wherein:
the through via further includes a penetrating portion extended in the one direction to cover an inner wall of the via hole and a plug disposed in a hollow portion in the penetrating portion.
